(19) United States
(12) Patent Application Publication
(10) Pub. No.: US 2014/0287161 A1
(43) Pub. Date: Sep. 25, 2014

(54) METHODS FOR COATING TUBULAR DEVICES USED IN OIL AND GAS DRILLING, COMPLETIONS AND PRODUCTION OPERATIONS

(71) Applicants: Mehmet D. Ertas, Bethlehem, PA (US); Michael B. Ray, Milford, NJ (US); Srinivasan Rajagopalan, Easton, PA (US); Bo Zhao, Houston, TX (US); Erika A. Ooten Biediger, St. Johns (CA)

(72) Inventors: Mehmet D. Ertas, Bethlehem, PA (US); Michael B. Ray, Milford, NJ (US); Srinivasan Rajagopalan, Easton, PA (US); Bo Zhao, Houston, TX (US); Erika A. Ooten Biediger, St. Johns (CA)

(73) Assignee: EXXONMOBIL RESEARCH AND ENGINEERING COMPANY, ANNANDALE, NJ (US)

(21) Appl. No.: 14/348,628

(22) PCT Filed: Oct. 3, 2012
(86) PCT No.: PCT/US2012/058562

§ 371 Date: Mar. 31, 2014

Related U.S. Application Data
(60) Provisional application No. 61/542,501, filed on Oct. 3, 2011.

(51) Int. Cl. C23C 14/28; C23C 16/513; C23C 16/48; C23C 14/35; C23C 14/32

(52) U.S. Cl. CPC C23C 14/28; C23C 14/35; C23C 14/325; C23C 16/486; C23C 16/513
USPC 427/569; 204/192.12; 204/192.38; 427/595; 427/596; 427/585

(57) ABSTRACT

Provided are methods and systems for vacuum coating the outside surface of tubular devices for use in oil and gas exploration, drilling, completions, and production operations for friction reduction, erosion reduction and corrosion protection. These methods include embodiments for sealing tubular devices within a vacuum chamber such that the entire device is not contained within the chamber. These methods also include embodiments for surface treating of tubular devices prior to coating. In addition, these methods include embodiments for vacuum coating of tubular devices using a multitude of devices, a multitude of vacuum chambers and various coating source configurations.

### FIELD

The present disclosure relates to the field of oil and gas exploration and well production operations. The present disclosure more particularly relates to the field of improved methods and systems for coating tubular devices. It still more particularly relates to improved methods and systems for vacuum coating tubular devices for use in oil and gas exploration, drilling, completions and production for friction reduction, erosion reduction and corrosion protection.

### BACKGROUND

The coating of sections of the outside diameter of tubular devices used in oil and gas exploration and production may provide advantages in certain applications requiring improved lubricity, wear protection, erosion protection and/or corrosion protection. However, the coating of the outside surface of long pieces of tubular devices used in such applications may be difficult due to the length and geometry of the tubular device for vacuum coating relative to the size and geometry of prior art vacuum coating equipment.

U.S. Pat. No. 7,608,151, herein incorporated by reference in its entirety, discloses a method and system for coating the internal surfaces of a localized area or section of a tubular devices by inserting into one or more openings of the tubular device conductive structures that define the section for coating.

In rotary drilling operations for oil and gas exploration, a drill bit is attached to the end of a bottom hole assembly which is attached to a drill string comprising drill pipe and tool joints which may be rotated at the surface by a rotary table or top drive unit. The weight of the drill string and bottom hole assembly causes the rotating bit to bore a hole in the earth. As the operation progresses, new sections of drill pipe are added to the drill string to increase its overall length. Periodically during the drilling operation, the open borehole is cased to stabilize the walls, and the drilling operation is resumed. As a result, the drill string usually operates both in the open borehole and within the casing which has been installed in the borehole. Alternatively, coiled tubing may replace drill string in the drilling assembly. The combination of a drill string and bottom hole assembly or coiled tubing and bottom hole assembly is referred to herein as a drill stem assembly. Rotation of the drill string provides power through the drill string and bottom hole assembly to the bit. In coiled tubing drilling, power is delivered to the bit by the drilling fluid pumps. The amount of power which can be transmitted by rotation is limited to the maximum torque a drill string or coiled tubing can sustain. Therefore, there is a need for new coating/material technologies that are casing-friendly while protecting the drill stem assembly from wear and at the same time lowering contact friction in cased hole drilling conditions, which requires novel materials that combine high hardness with a capability for low coefficient of friction (COF) when in contact with the casing steel surface. U.S. patent application Ser. No. 13/042,761, herein incorporated by reference in its entirety, entitled “Ultra-Low Friction Coatings For Drill Stem Assemblies” addresses this need by disclosing drill stem assemblies with ultra-low friction coatings for subterraneous drilling operations.

Oil and gas well production suffers from basic mechanical problems that may be costly, or even prohibitive, to correct, repair, or mitigate. Friction is ubiquitous in the oilfield, devices that are in moving contact wear and lose their original dimensions, and devices are degraded by erosion, corrosion, and deposits. These are impediments to successful operations that may be mitigated by selective use of coated oil and gas well production devices and coated sleeved oil and gas well production devices. Therefore, there is a need for the application of new coating material technologies for coated oil and gas well production devices and coated sleeved oil and gas well production devices that protect such devices from friction, wear, corrosion, erosion, and deposits resulting from sliding contact between two or more devices and fluid flow streams that may contain solid particles traveling at high velocities. U.S. patent application Ser. No. 13/032,032, herein incorporated by reference in its entirety, entitled “Coated Sleeved Oil And Gas Well Production Devices” addresses this need by disclosing coated sleeved oil and gas well production devices and methods of making and using such coated sleeved devices. U.S. patent application Ser. No. 13/075,677, herein incorporated by reference in its entirety, entitled “Coated Oil And Gas Well Production Devices” also addresses this need by disclosing coated oil and gas well production devices and methods of making and using such coated devices.

As described in these patent applications, it is desirable in some cases to place coatings on portions of tubular devices for various reasons including friction reduction, erosion reduction, and corrosion protection. The methods to apply the coatings on tubular devices that form drill stem assemblies and production devices generally require that the body be enclosed in a vacuum chamber for coating. This may be a very restrictive requirement for many oilfield components. For example, the length and geometry of long pipe sections may be cumbersome for vacuum coating chambers to handle. This is also not likely to be very efficient since the surface area to be coated may be a small fraction of the total surface area of the main body.

The current state of the art is to place the entire tubular in a vacuum chamber if the deposition involves a vacuum process. The method of placing a coating on the surface includes cleaning and polishing the surface and pulling a vacuum on the entire chamber. This can be extremely difficult when the piece that needs to be coated is larger than what typical vacuum chambers can accommodate. For example, to coat a portion of a drill string tubular (joint of pipe), it would require: 1) cleaning the entire length of pipe, 2) placing the entire 30′ piece of pipe into a big enough chamber, and then 3) pulling and maintaining a vacuum to generate an environment conducive to depositing a CVD, PVD, PACVD, or ARC deposition coating on the member. The typical vacuum fir coating is generally 10⁻⁵ millibar or less.

If it is necessary to coat a component that has already been in service, there may be a lot of contaminants (mud, grease, hydrocarbons, scale, accretion, etc.), corrosion (pitting, etc.), surface roughness (gouges, small cracks, uneven wear, etc.) present on the object that must be removed prior to placing it in the vacuum chamber in order to avoid contamination of the coating and unwanted morphological properties. Trying to create a vacuum seal in the presence of contaminants or surface imperfections is extremely difficult.

Hence, there is a need for improved systems and methods for vacuum sealing, surface cleaning and vacuum coating the outside of a tubular device used in oil and gas drilling and production operations.

### SUMMARY

According to the present disclosure, an advantageous method for coating a tubular device used in oil and gas drilling and production comprises positioning one or more tubular devices in a vacuum chamber for coating with improved methods for sealing the tubular devices within the vacuum chamber such that the entire device is not contained within the chamber.

A further aspect of the present disclosure relates to an advantageous method for coating a tubular device used in oil and gas drilling and production comprising wherein the tubular devices are surface treated prior to coating.

Another aspect of the present disclosure relates to an advantageous method for coating a tubular device used in oil and gas drilling and production comprising vacuum coating of tubular devices using a multitude of devices, a multitude of vacuum chambers and various coating source configurations.

In one aspect of the present disclosure, a method of coating a portion of the outer surface of a tubular device used in oil and gas drilling, completions and production operations comprises: providing one or more tubular devices and one or more vacuum coating chambers, positioning the one or more tubular devices in the one or more vacuum coating chambers, wherein at least a portion of the one or more tubular devices extends outside of the one or more vacuum coating chambers, forming one or more vacuum seals between the outside surface of the one or more tubular devices and one or more walls of the one or more vacuum coating chambers, pulling a vacuum inside the one or more vacuum coating chambers around one or more portions of the outer surface of the one or more tubular devices for coating, and forming a coating on one or more portions of the outer surface of the one or more tubular devices via a vacuum deposition method.

These and other features and attributes of the disclosed methods for coating a tubular device used in oil and gas drilling, completions and production of the present disclosure and their advantageous applications and/or uses will be apparent from the detailed description which follows, particularly when read in conjunction with the figures appended hereto.

### DEFINITION

“Oil-country tubular goods” (OCTG) (also referred to as “tubulars” or “tubular devices”) comprise drill stem equipment, casing, tubing, work strings, coiled tubing, pipes, and risers. Common to most OCTG (but not coiled tubing) are threaded connections, which are subject to potential failure resulting from improper thread and/or seal interference, leading to galling in the mating connectors that can inhibit use or reuse of the entire joint of pipe due to a damaged connection. Threads may be shot-peened, cold-rolled, and/or chemically treated (e.g., phosphate, copper plating, etc.) to improve their anti-galling properties, and application of an appropriate pipe thread compound provides benefits to connection usage. However, there are still problems today with thread galling and interference issues, particularly with the more costly OCTG material alloys for extreme service requirements. Operations using OCTG often involve the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

“Completion strings and equipment” is defined as the equipment used when the drill well is cased to prevent hole collapse and uncontrolled fluid flow. The completion operation must be performed to make the well ready for production. This operation involves running equipment into and out of the wellbore to perform certain operations such as cementing, perforating, stimulating, and logging. Two common means of conveyance of completion equipment are wireline and pipe (drill pipe, coiled tubing, or tubing work strings). These operations may include running logging tools to record formation and fluid properties, perforating guns to make holes in the casing to allow hydrocarbon production or fluid injection, temporary or permanent plugs to isolate fluid pressure, packers to facilitate setting pipe to provide a seal between the pipe interior and annular areas, and additional types of equipment needed for cementing, stimulating, and completing a well. Wireline tools and work strings may include packers, straddle packers, and casing patches, in addition to packer setting tools, devices to install valves and instruments in sidepockets, and other types of equipment to perform a downhole operation. The placement of these tools, particularly in extended-reach wells, may be impeded by friction drag. The final completion string left in the hole for production is commonly referred to as the production tubing string. Installation and use of completion strings and equipment often involves the axial or torsional motion of one body relative to another, wherein the two bodies are in mechanical contact with a certain contact force and contact friction that resists the relative motion causing friction and wear. Such motion may be required for installation after which the device may be substantially stationary, or for repeated applications to perform some operation.

“Drill string” is defined as the column, or string of drill pipe with attached tool joints, transition pipe between the drill string and bottom hole assembly including tool joints, heavy weight drill pipe including tool joints and wear pads that transmits fluid and rotational power from the kelly to the drill collars and the bit. Often, especially in the oil patch, the term is loosely applied to include both drill pipe and drill collars. The drill string does not include the drill bit.

“Drill stem” is defined as the entire length of tubular pipes, composed of the kelly, the drill pipe, and drill collars, that make up the drilling assembly from the surface to the bottom of the hole. The drill stem does not include the drill bit. Recently, in an innovative development, the industry has used casing and liner tubulars in the drill stem assembly.

“Bottom hole assembly” (BHA) is defined as one or more components, including but not limited to: stabilizers, variable-gauge stabilizers, back reamers, drill collars, flex drill collars, rotary steerable tools, roller reamers, shock subs, mud motors, logging while drilling (LWD) tools, measuring while drilling (MWD) tools, coring tools, under-reamers, hole openers, centralizers, turbines, bent housings, bent motors, drilling jars, acceleration jars, crossover subs, bumper jars, torque reduction tools, float subs, fishing tools, fishing jars, washover pipe, logging tools, survey tool subs, non-magnetic counterparts of these components, associated external connections of these components, and combinations thereof.

“Drill stem assembly” is defined as a combination of a drill string and bottom hole assembly, a coiled tubing and bottom hole assembly, or a casing string and bottom hole assembly. The drill stern assembly does not include the drill bit.

A “coating” is comprised of one or more adjacent layers and any included interfaces. A coating may be placed on the base substrate material of a body assembly, on the hardbanding placed on a base substrate material, or on another coating.

An “ultra-low friction coating” is a coating for which the coefficient of friction is less than 0.15 under reference conditions.

A “layer” is a thickness of a material that may serve a specific functional purpose such as reduced coefficient of friction, high stiffness, or mechanical support for overlying layers or protection of underlying layers.

An “ultra-low friction layer” is a layer drat provides low friction in an ultra-low friction coating.

A “non-graded layer” is a layer in which the composition, microstructure, physical, and mechanical properties are substantially constant through the thickness of the layer.

A “graded layer” is a layer in which at least one constituent, element, component, or intrinsic property of the layer changes over the thickness of the layer or some fraction thereof.

A “buffer layer” is a layer interposed between two or more ultra-low friction layers or between an ultra-low friction layer and buttering layer or hardbanding. There may be one or more buffer layers included within the ultra-low friction coating. A buffer layer may also be known as an “interlayer” or an “adhesive layer.”

A “buttering layer” is a layer interposed between the outer surface of the body assembly substrate material or hardbanding and a layer, which may be another buttering layer, a buffer layer, or an ultra-low friction layer. There may be one or more buttering layers interposed in such a manner.

“Hardbanding” is a layer interposed between the outer surface of the body assembly substrate material and the buttering layer(s), buffer layer, or ultra-low friction coating. Hardbanding may be utilized in the oil and gas drilling industry to prevent tool joint and casing wear.

“CVD” is Chemical Vapor Deposition.

“PVD” is Plasma Vapor Deposition.

“PACVD” is Plasma Assisted Chemical Vapor Deposition.

“DLC” is diamond like carbon coating.

### BRIEF DESCRIPTION OF DRAWINGS

To assist those of ordinary skill in the relevant art in making and using the subject matter hereof, reference is made to the appended drawings, wherein:

FIG. 1 depicts an exemplary schematic of a vacuum chamber, a tubular device and a single seal.

FIG. 2 depicts an alternative exemplary schematic of two vacuum chambers, tubular device and two seals.

FIG. 3 depicts an alternative exemplary schematic of a vacuum chamber, a tubular device and a two seals on either side of where vacuum is desired.

FIG. 4 depicts an alternative exemplary schematic of the embodiment of FIG. 3 with a sacrificial sealing surface.

FIG. 5 depicts an alternative exemplary schematic of the embodiment of FIG. 4 where the sealing surface is not contiguous to the area where a vacuum is desired.

FIG. 6 depicts an alternative exemplary schematic of a multi-stage vacuum chamber, a tubular device and successive seals.

FIG. 7 depicts an alternative exemplary schematic of a vacuum chamber with multiple targets or sources around the circumference of the vacuum chamber.

FIG. 8 depicts an alternative exemplary schematic of a single vacuum chamber with multiple tubular devices contained within it for coating.

FIG. 9 depicts an alternative exemplary schematic of a multiple vacuum chamber assembly for coating multiple tubular devices.

### DETAILED DESCRIPTION

All numerical values within the detailed description and the claims herein are modified by “about” or “approximately” the indicated value, and take into account experimental error and variations that would be expected by a person having ordinary skill in the art.

The present disclosure provides novel methods for coating tubular devices used in oil and gas drilling and production/completion operations. A particularly advantageous method for coating tubular devices is provided for drilling applications and could be used for any member of the drill assembly, such as for multiple areas on multiple connected pieces of tubular.

The methods are distinguishable over the prior art in providing novel methods of pulling a high vacuum on tubular devices during the vacuum coating process by improved sealing methods of the tubular devices. These methods of the present disclosure offer significant advantages relative to prior art methods, including, but not limited to, lower cost coating production, ability to coat and repair tubular devices in the field, enhanced coating productivity, enhanced coating flexibility and the ability to coat very large tubular devices that will not fit into traditional coating vacuum chambers.

### Coating Processes

The coating processes disclosed herein include physical vapor deposition, chemical vapor deposition, or plasma assisted chemical vapor deposition coating techniques. The physical vapor deposition coating methods include magnetron sputtering, ion beam assisted deposition, cathodic arc deposition and pulsed laser deposition (PLD). The chemical vapor deposition coating methods include ion beam assisted CVD deposition, plasma enhanced deposition using a glow discharge from hydrocarbon gas, using a radio frequency (r.f.) glow discharge from a hydrocarbon gas, plasma immersed ion processing and microwave discharge. Plasma assisted chemical vapor deposition (PACVD) is one advantageous method for depositing low friction DLC coatings on large areas at high deposition rates. PACVD is also commonly referred to as plasma enhanced chemical vapor deposition (PECVD). Plasma-based CVD coating process is a non-line-of-sight technique, i.e. the plasma conformally covers the part to be coated and the entire exposed surface of the part is coated with uniform thickness. The surface finish of the part may be retained after the DLC coating application. One advantage of PACVD is that the temperature of the substrate part does not increase above about 150° C. during the coating operation. The fluorine-containing DLC (F-DLC) and silicon-containing DLC (Si-DLC) films can be synthesized using plasma deposition technique using a process gas of acetylene (C₂H₂) mixed with fluorine-containing and silicon-containing precursor gases respectively (e.g., tetra-fluoro-ethane and hexa-methyl-disiloxane)

### Sealing for Improved Vacuum Embodiments

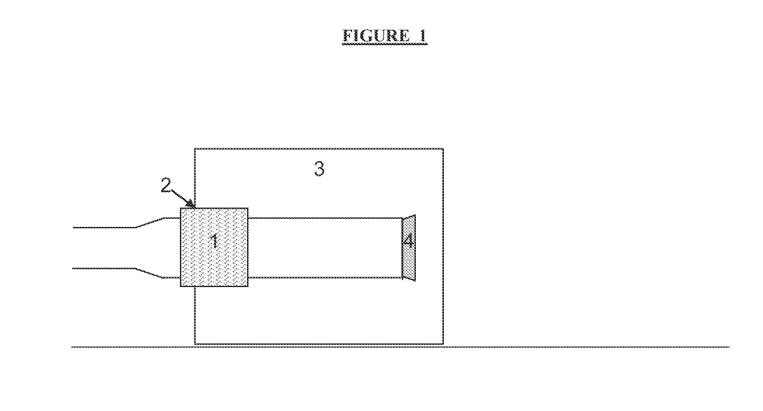

In one exemplary embodiment of the present disclosure depicted in FIG. 1, the method for coating a tubular device used in oil and gas drilling and production includes the steps of providing a tubular device for coating with hardbanding 1, capping the end of the tubular device with a gas-tight end cap 4 to isolate the inside diameter (ID) of the tubular device, placing the capped end of the tubular device in a coating vacuum chamber 3, and forming a seal 2 against the outside diameter (OD) of the tubular device to allow for a vacuum to be pulled in the vacuum chamber 3 on a section of the tubular between the OD seal 2 and the end of the tubular device. This section would include the capped member. This exemplary embodiment allows for large tubular devices to be vacuum coated without the need to put the entire device within the vacuum chamber.

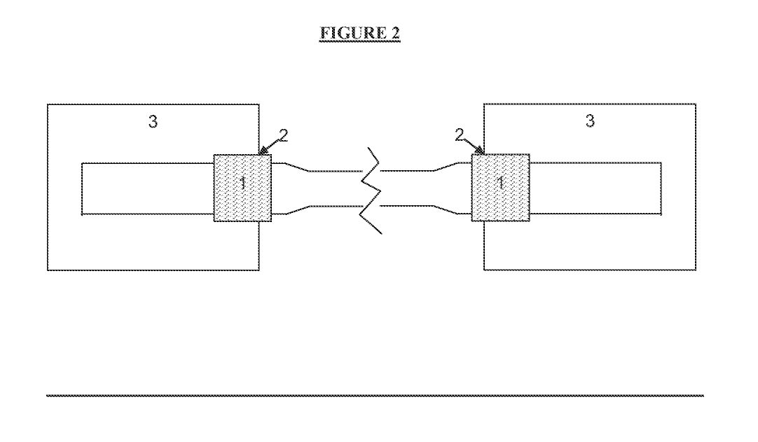

In an alternative embodiment of the present disclosure depicted in FIG. 2, the method for coating a tubular device used in oil and gas drilling and production includes the steps of providing a tubular device for coating with hardbanding 1, placing each end of the tubular device in two coating vacuum chambers 3, and then forming two OD seals 2. This embodiment creates a single seal near each end of the tubular to create a vacuum on the distal end of both the OD seals and the entire ID of the tubular.

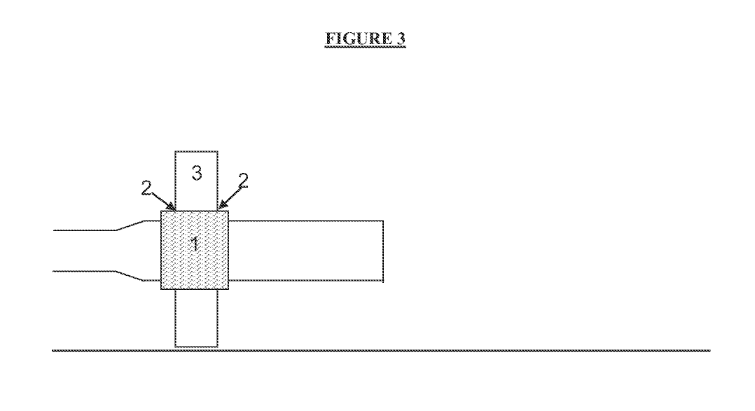

In an alternative embodiment of the present disclosure depicted in FIG. 3, the tubular device for coating 1 is placed in a vacuum chamber 3 with both ends of the device passing through the ends of the vacuum chamber 3. In this form, there would be seals 2 formed on either side of where the vacuum is desired. In an alternative form of the embodiment presented in FIG. 3, a fast curing epoxy or other suitable adhesive, such as a urethane adhesive, may be applied to the outside surface of the tubular device 1 for coating. The epoxy or other suitable adhesive would conform to the surface conditions and mitigate any surface imperfections present thus enabling reaching a high vacuum seal. The seal between the chamber and the Object to be coated would be created by the epoxy.

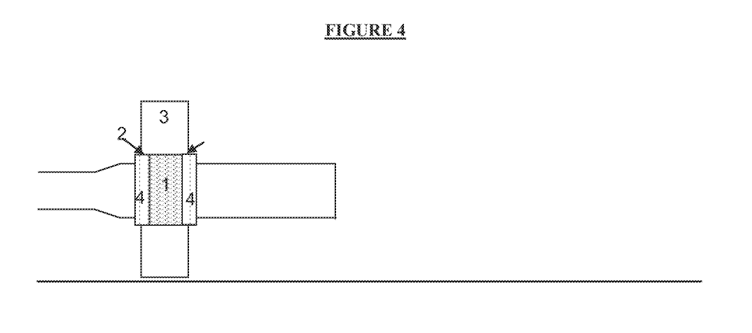

In still another embodiment of the present disclosure depicted in FIG. 4, for any seal required on the surface of the OD of the tubular device 1 for coating in a vacuum chamber 3, a “sacrificial surface” 4 against which a good seal 2 can be formed may be generated. Advantageously the seal material 4 is plastically deformable such that it conforms and “fills in” any cracks or voids or surface imperfections present in the surface. Alternatively, a soft or ductile material to push against the sealing surface may be used. In one form, a knife edge on the vacuum chamber is pushed against the ductile material to form a vacuum seal. Non-limiting exemplary ductile materials include aluminum, steel, copper, tin, or alloys of aluminum, iron, copper, and tin, or a plastic/resin material. Non-limiting exemplary application methods for the ductile material include: heat welding, soldering, friction stir welding, vacuum grease, and Viton® seals. In another embodiment, one or more vacuum seal adapters designed to form a type of conventional vacuum seal may be attached to the tubular device using any of the aforementioned methods. An alternative form of this embodiment would be to extend the width of a hardbanding area 1 for the purpose of forming the seal. In another form, the height of the extended hardbanding area 1 may be slightly proud relative to the tool joint, and may not be the same height as the hardbanding. The composition of the sacrificial material may then be varied to promote sealability. For example, while applying hardbanding 1 to the tubular device, the edges can be made to be softer and relatively crack-free to promote sealability, whereas the middle portion of the hardbanding 1 may be harder, and hence retain the desired properties of the hardbanding. In one advantageous form, the edges of the hardbanding may be of a lower height relative to the center so that the contact area of the hardbanding 1 which it will experience during service is entirely inside the vacuum chamber 3 and is coated.

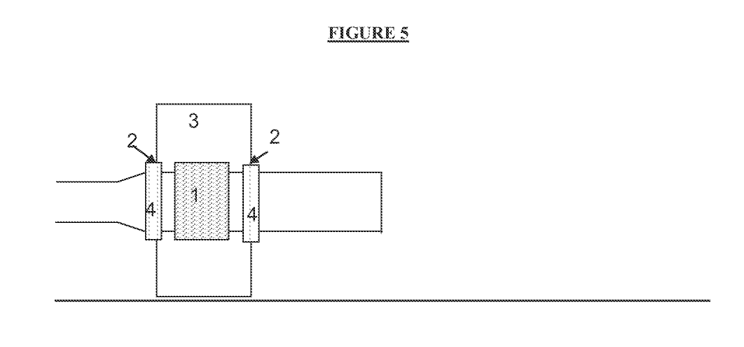

In still another embodiment of the present disclosure depicted in FIG. 5, the sealing surface 4 is not contiguous to the area where the vacuum is desired. That is, the surface to be coated 1 is not adjacent to the sealing surface 4. The seals 2 are formed between the OD of the tubular device and the vacuum chamber 3 for coating. One benefit of this embodiment is that the sealing surface 2 can be of a different composition, morphology, and/or surface properties than the surface 1 to be coated requiring a vacuum.

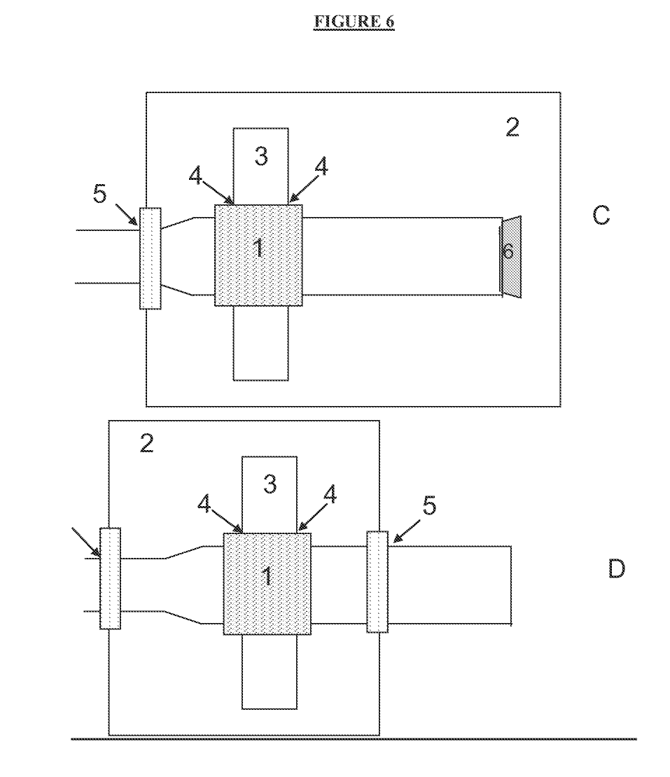

In still another embodiment of the present disclosure depicted in FIG. 6, a multi-stage vacuum chamber including an outer chamber 2 and an inner chamber 3 may be utilized to provide a staged approach to obtaining the needed vacuum levels for coating. Using this approach, there are outer seals 5 used for outer vacuum chamber 2 and another set of inner seals 4 for inner vacuum changer 3. Each of the successive seals (5 to 4) may provide an additional barrier to enable a high vacuum seal at the inner-most stage even if the individual seals are not suitable by themselves. At the final stage, the combination of seals provides the necessary sealing containment, such that the required vacuum level for coating may be reached. One of the stages may be a jet(s) of air similar to an “air door” such as to provide a barrier against the atmosphere. In one form of this embodiment (C in FIG. 6), the outer chamber has only one seal 5 and a gas-tight end cap 6, whereas in another form of this embodiment (D in FIG. 6), the outer chamber has two or more seals.

### Surface Treatment Embodiments

Various surface treatment methods may also be optionally utilized on the OD surface of the tubular device for coating. In particular, the vacuum seal methods described above may also optionally use surface treatment methods to improve the quality of the seal by changing the surface properties of the tubular device, for example, to improve wettability and affinity to the sealing material. For example, changing the surface energy of the OD surface of the tubular device by application of a siloxane self assembled mono layer may improve the wettability and surface energy of the epoxy described in FIG. 3 above. This would create a chemical bond between the tubular device and the seal substrate and generate the necessary surface properties for the sealing agent to wet the surface of the tubular device. Another form of modifying the surface of the tabular device for seal attachment may be to plate a portion of the surface (sealing area) with a material that has different surface properties. In one exemplary form, an electroless plating of NiP may be applied to the OD surface of the tubular device to provide a smooth, clean and ductile sealing surface.

Non-limiting exemplary surface treatment methods that may be applied to the tubular device in preparation for coating include ultra sonic cleaning, polishing, etching, grinding, solvent cleaning, sand blasting, and applying hardbanding and combinations thereof.

### Vacuum Coating of Tubular Devices Methods Embodiments

The tubular devices after being subjected to the preparation methods described above may be vacuum coated with one or more coating layers. Ultra-low friction coatings and hardbanding are exemplary, non-limiting coatings that may be applied. Representative, non-limiting coating processes for applying such coatings include, CVD, PVD, PACVD and ARC deposition methods. These coating processes typically require that tubular devices be rotated within the vacuum chamber to provide for line of sight, and hence uniform coating thickness around the circumference of the part.

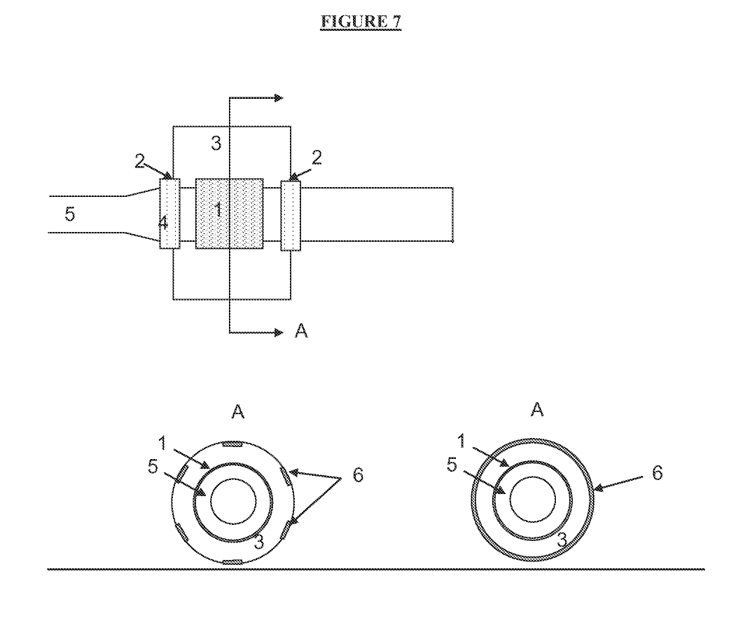

In one embodiment of the coating processes described above, the tubular device for coating is not rotated in the vacuum chamber, but instead utilizes multiple coating targets or sources that are positioned around or wrap around the vacuum chamber as shown in FIG. 7. Referring to FIG. 7, cross-section A depicts the chamber 3, the tubular device 5 for coating, the outside surface 1 of the tubular device 5 for coating, and the sources 6 positioned around the circumference of the tubular device 5. This coating configuration may provide for coating a surface of a tubular device at an accelerated rate. Alternatively, the vacuum chamber may have a bellows structure to allow for relative movement of the tubular with respect to the chamber. The chamber may also optionally be installed with a rocker to enable some relative movement between the tubular and the chamber.

In another embodiment of the coating processes described above, the coating source geometry may be rotated within the vacuum chamber while the tubular device remains fixed in position. This allows for the outside surface of the tubular device to be uniformly coated without rotating the tubular device. This embodiment may be particularly effective for large tubular devices that are difficult to rotate and that would require too many individual sources positioned around the circumference.

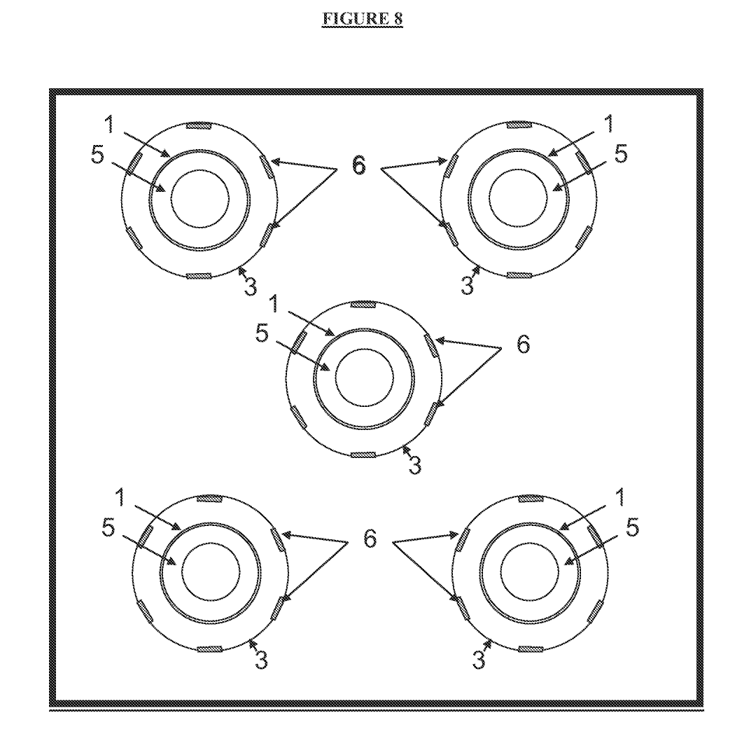

In another embodiment of the coating processes disclosed herein, a single vacuum chamber may coat two or more tubular devices simultaneously. Referring to FIG. 8, a total of five tubular devices 5 are positioned in a single vacuum chamber 7. Each tubular device 5 has a source holder 3 with a multitude of sources 6 positioned in the source holder 3 for coating the outside surface 1 of the tubular device 5. This embodiment allows for higher productivity rates. The number of tubular devices that may be simultaneously vacuum coated using this embodiment may be two, or three, or four, or five, or six, or seven, or eight, or nine, or ten, or more.

In yet another embodiment of the coating processes disclosed herein, separate coating chambers may be used for the cleaning of the surface of the tubular and then coating the cleaned surface. Between the cleaning and the coating chamber may be a transition section under a partial vacuum to help minimize contamination of the tubular device after the cleaning step and prior to the coating step.

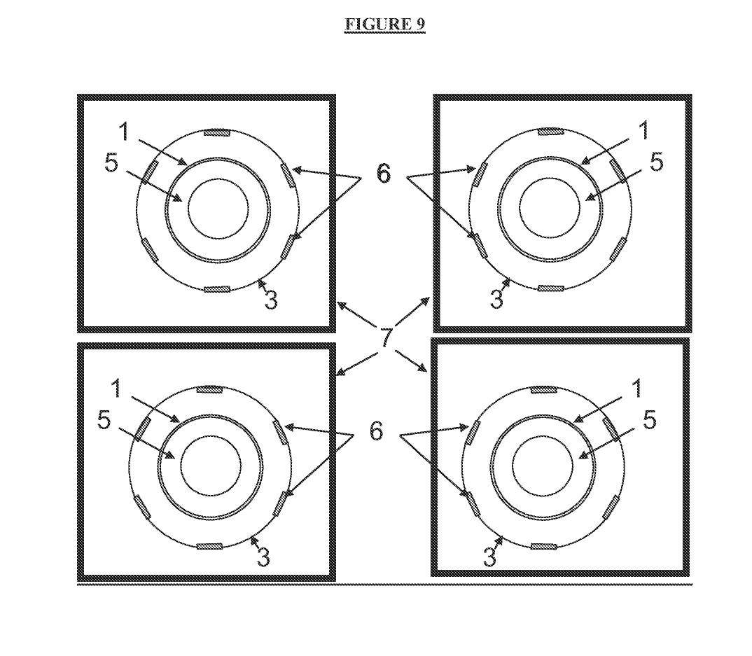

In still yet another embodiment of the coating processes disclosed, individual coating chambers may be used for cleaning and coating a multitude of tubular devices simultaneously. Referring to FIG. 9, a total of four tubular devices 5 are positioned in 4 separate vacuum chambers 7. Each chamber 7 has a source holder 3 with a multitude of sources 6 positioned in the source holder 3 for coating the outside surface 1 of the tubular device 5. In this embodiment, each tubular device 5 has its own vacuum chamber 7, but is connected to a central vacuum system and power grid for the system, thus allowing for adjustments to the number of tubular devices 5 that may be coated at any given time. Such an arrangement can also reduce the overall volume in the vacuum chamber that needs to be evacuated. Alternatively, a high vacuum can be reached in multiple stages by sequentially connecting each chamber to vacuum pumps that can progressively pull higher vacuum levels. Each stage can utilize the most efficient type of vacuum pump for the pressure range associated with the stage. Multiple chambers then allow each pump to operate nearly continuously. This embodiment also allows for higher productivity rates. The number of tubular devices that may be vacuum coated in individual chambers using this embodiment may be two, or three, or four, or five, or six, or seven, or eight, or nine, or ten, or more.

### Coating Types and Coating Layers

The coatings or ultra-low friction coatings that may be deposited onto tubular devices using the methods described herein may include one or more ultra-low friction layers chosen from an amorphous alloy, an electroless nickel-phosphorous composite, graphite, MoS₂, WS₂, a fullerene based composite, a boride based cermet, a quasicrystalline material, a diamond based material, diamond-like-carbon (DLC), boron nitride, chromium nitride, silicon nitride, silicon carbide, carbon nanotubes, graphene sheets, metallic particles of high aspect ratio (i.e. relatively long and thin), ring-shaped materials (e.g. carbon nanorings), oblong particles and combinations thereof. The diamond-based material may be chemical vapor deposited (CVD) diamond or polycrystalline diamond compact (PDC). The composition of the ultra-low friction coating may be uniform or variable through its thickness. In one advantageous embodiment, the tubular device is coated with a diamond-like-carbon (DLC) coating, and more particularly the DLC coating may be chosen from tetrahedral amorphous carbon (ta-C), tetrahedral amorphous hydrogenated carbon (ta-C:H), diamond-like hydrogenated carbon (DLCH), polymer-like hydrogenated carbon (PLCH), graphite-like hydrogenated carbon (GLCH), silicon containing diamond-like-carbon (Si-DLC), titanium containing diamond-like-carbon (Ti-DLC), chromium containing diamond-like-carbon (Cr-DLC), metal containing diamond-like-carbon (Me-DLC), oxygen containing diamond-like-carbon (O-DLC), nitrogen containing diamond-like-carbon (N-DLC), boron containing diamond-like-carbon (B-DLC), fluorinated diamond-like-carbon (F-DLC), sulfur-containing diamond-like carbon (S-DLC), and combinations thereof. These one or more ultra-low friction layers may be graded for improved durability, friction reduction, adhesion, and mechanical performance.

The coefficient of friction of the coating, also referred to as an ultra-low friction coating, may be less than or equal to 0.15, or 0.13, or 0.11, or 0.09 or 0.07 or 0.05. The friction force may be calculated as follows: Friction Force=Normal Force×Coefficient of Friction. In another form, the coated tubular may have a dynamic friction coefficient of the coating that is not lower than 50%, or 60%, or 70%, or 80% or 90% of the static friction coefficient of the coating. In yet another form, the coated tubular may have a dynamic friction coefficient of the coating that is greater than or equal to the static friction coefficient of the coating.

Significantly decreasing the coefficient of friction (COF) of the coated tubular will result in a significant decrease in the friction force. This translates to a smaller force required to slide the objects along the surface. Lowering the COF is accomplished by coating these surfaces with coatings disclosed herein. These coatings are able to withstand the aggressive environments of drilling and production including resistance to erosion, corrosion, impact loading, and exposure to high temperatures.

In addition to low COF, the coatings of the present disclosure are also of sufficiently high hardness to provide durability against wear during drilling and completion operations. More particularly, the Vickers hardness or the equivalent Vickers hardness of the coatings disclosed herein may be greater than or equal to 400, 500, 600, 700, 800, 900, 1000, 1500, 2000, 2500, 3000, 3500, 4000, 4500, 5000, 5500, or 6000. A Vickers hardness of greater than 400 allows for the tubular devices to be used for drilling in shales with water based muds and the use of spiral stabilizers. Spiral stabilizers have less tendency to cause BHA vibrations than straight-bladed stabilizers. The combination of low COF and high hardness for the coatings disclosed herein when used as a surface coating on tubular devices provides for hard, low COF durable materials for downhole drilling and completion applications.

The coating or ultra-low friction coating disclosed herein may include one or more ultra-low friction layers, one or more buttering layers, one or more buffer layers, and any combinations thereof, forming a multilayer coating. This multilayer coating may be placed directly onto a base substrate material or, in another non-limiting embodiment, placed on a portion of a hardhanded material interposed between the coating and the base substrate material.

The tubular device may be fabricated from iron based materials, carbon steels, steel alloys, stainless steels, Al-base alloys, Ni-base alloys and Ti-base ceramics, cermets, and polymers. 4142 type steel is one non-limiting exemplary material. The surface of the tubular device may be optionally subjected to an advanced surface treatment prior to coating application to form a buttering layer, upon which a coating may be applied forming a multilayer coating. Other exemplary non-limiting substrate materials may be used, such as tungsten-carbide cobalt. The buttering layer may provide one or more of the following benefits: extended durability, enhanced wear resistance, reduced friction coefficient, enhanced fatigue and extended corrosion performance of the overall coating. The one or more buttering layers is formed by one or more of the following non-limiting exemplary processes chosen from: PVD, PACVD, CVD, ion implantation, carburizing, nitriding, boronizing, sulfiding, oxidizing, an electrochemical process, an electroless plating process, a thermal spray process, a kinetic spray process, a laser-based process, a friction-stir process, a shot peening process, a laser shock peening process, a welding process, a brazing process, an ultra-fine superpolishing process, a tribochemical polishing process, an electrochemical polishing process, and combinations thereof. Such surface treatments may harden the substrate surface and retard plastic deformation by introducing additional species and/or introduce deep compressive residual stress resulting in inhibition of the crack growth induced by fatigue, impact and wear damage. A Vickers hardness of greater than 400 is required, preferably Vickers hardness values in excess of 950 to exceed hardbanding, 1500 to exceed quartz particles, and 1700 to exceed the hardness of other layers are desired. The buttering layer may be a structural support member for overlying layers of the coating.

In another embodiment of the methods of coating the tabular devices disclosed herein, the tubular device may include hardbanding on at least a portion of the exposed outer surface to provide enhanced wear resistance and durability. The one or more coating layers are deposited on top of the hardbanding. The thickness of hardbanding layer may range from several orders of magnitude times that of or equal to the thickness of the outer coating layer. Non-limiting exemplary hardbanding thicknesses are 1 mm, 2 mm, and 3 mm proud above the surface of the tubular device. Non-limiting exemplary hardbanding materials include cermet based materials, metal matrix composites, nanocrystalline metallic alloys, amorphous alloys and hard metallic alloys. Other non-limiting exemplary types of hardbanding include carbides, nitrides, borides, and oxides of elemental tungsten, titanium, niobium, molybdenum, iron, chromium, and silicon dispersed within a metallic alloy matrix. Such hardbanding may be deposited by weld overlay, thermal spraying or laser/electron beam cladding.

In yet another embodiment of the methods of coating the tubular devices disclosed herein, the multilayer ultra-low friction coating may further include one or more buttering layers interposed between the outer surface of the tubular or hardbanding layer and the ultra-low friction layers on at least a portion of the exposed outer surface. Buttering layers may serve to provide enhanced toughness, to enhance load carrying capacity, to reduce surface roughness, to inhibit diffusion from the base substrate material or hardbanding into the outer coating, and/or to minimize residual stress absorption. Non-limiting examples of buttering layer materials are the following: a stainless steel, a chrome-based alloy, an iron-based alloy, a cobalt-based alloy, a titanium-based alloy, or a nickel-based alloy, alloys or carbides or nitrides or carbo-nitrides or borides or silicides or sulfides or oxides of the following elements: silicon, titanium, chromium, aluminum, copper, iron, nickel, cobalt, molybdenum, tungsten, tantalum, niobium, vanadium, zirconium, hafnium, or combinations thereof. The one or more buttering layers may be graded for improved durability, friction reduction, adhesion, and mechanical performance.

Ultra-low friction coatings may possess a high level of intrinsic residual stress (˜1 GPa) which has an influence on their tribological performance and adhesion strength to the substrate (e.g., steel) for deposition. In order to benefit from the low friction and wear/abrasion resistance benefits of ultra-low friction coatings for tubulars disclosed herein, they also need to exhibit durability and adhesive strength to the outer surface of the body assembly for deposition.

Typically ultra-low friction coatings deposited directly on steel surface suffer from poor adhesion strength. This lack of adhesion strength restricts the thickness and the incompatibility between ultra-low friction coating and steel interface, which may result in delamination at low loads. To overcome these problems, in one embodiment, the ultra-low friction coatings disclosed herein may also include buffer layers of various metallic (for example, but not limited to, Cr, W, Ti, Ta), semimetallic (for example, but not limited to, Si) and ceramic compounds (for example, but not limited to, CrₓN, TiN, ZrN, AlTiN, SiC, TaC) between the outer surface of the tubular and the ultra-low friction layer. These ceramic, semimetallic and metallic buffer layers relax the compressive residual stress of the ultra-low friction coatings disclosed herein to increase the adhesion and load carrying capabilities. An additional approach to improve wear, friction, and mechanical durability of the ultra-low friction coatings disclosed herein is to incorporate multiple ultra-low friction layers with intermediate buffer layers to relieve residual stress build-up.

The coatings for use in tubulars disclosed herein may also include one or more buffer layers (also referred to herein as adhesive layers or interlayers). The one or more buffer layers may be interposed between the outer surface of the body assembly, hardbanding, or buttering layer, and the single layer or the two or more layers in a multilayer coating configuration. The one or more buffer layers may be chosen from the following elements or alloys of the following elements: silicon, aluminum, copper, molybdenum, titanium, chromium, tungsten, tantalum, niobium, vanadium, zirconium, and/or hafnium. The one or more buffer layers may also be chosen from carbides, nitrides, carbo-nitrides, oxides of the following elements: silicon, aluminum, copper, molybdenum, titanium, chromium, tungsten, tantalum, niobium, vanadium, zirconium, and/or hafnium. The one or more buffer layers are generally interposed between the hardbanding (when utilized) and one or more coating layers or between ultra-low friction layers. The buffer layer thickness may be a fraction of, or approach, or exceed the thickness of an adjacent ultra-low friction layer. The one or more buffer layers may be graded for improved durability, friction reduction, adhesion, and mechanical performance. A buffer layer may be interposed between any other layers, including another buffer layer or one or more buttering layers.

In another embodiment of the methods of coating the tubular devices disclosed herein, the hardbanding surface has a patterned design to reduce entrainment of abrasive particles that contribute to wear. The ultra-low friction coating is deposited on top of the hardbanding pattern. The hardbanding pattern may include both recessed and raised regions and the thickness variation in the hardbanding can be as much as its total thickness.

In another embodiment, the buttering layer may be used in conjunction with hardbanding, where the hardbanding is on at least a portion of the exposed outer or inner surface to provide enhanced wear resistance and durability to the coated tubular, where the hardbanding surface may have a patterned design that reduces entrainment of abrasive particles that contribute to wear. In addition, one or more ultra-low friction coating layers may be deposited on top of the buttering layer to form a multilayer coating.

The coated tubulars disclosed herein also provide a surface energy less than 1, 0.9, 0.8, 0.7, 0.6, 0.5, 0.4, 0.3, 0.2, or 0.1 J/m². In subterraneous rotary drilling operations, this helps to mitigate sticking or balling by rock cuttings. Contact angle may also be used to quantify the surface energy of the coatings on the coated tubulars disclosed herein. The water contact angle of the coatings disclosed herein is greater than 50, 60, 70, 80, or 90 degrees. Ultra-low friction coatings used on a hardbanding on at least a portion of the exposed outer surface of the body assembly, where the hardbanding surface has a patterned design that reduces entrainment of abrasive particles that contribute to wear, will also mitigate sticking or balling by rock cuttings. In one embodiment, such patterns may reduce the contact area by 1.0%-90% between hardbanding and casing or open borehole and reduce accumulation of cuttings.

In a further advantageous embodiment, one or more interfaces between the layers in a multilayer ultra-low friction coating are graded interfaces. The interfaces between various layers in the coating may have a substantial impact on the performance and durability of the coating. In particular, non-graded interfaces may create sources of weakness including one or more of the following: stress concentrations, voids, residual stresses, spallation, delamination, fatigue cracking, poor adhesion, chemical incompatibility, mechanical incompatibility. Graded interfaces allow for a gradual change in the material and physical properties between layers, which reduces the concentration of sources of weakness. The thickness of each graded interface may range from 10 nm to 10 microns, or 20 nm to 500 nm, or 50 nm to 200 nm. Alternatively the thickness of the graded interface may range from 5% to 100% of the thickness of the thinnest adjacent layer.

In a further advantageous embodiment, graded interfaces may be combined with the one or more ultra-low friction, buttering, and buffer layers, which may be graded and may be of similar or different materials, to further enhance the durability and mechanical performance of the coating,

### Other Embodiments and EP Clauses

1. A method of coating a portion of the outer surface of a tubular device used in oil and gas drilling, completions and production operations comprises: providing one or more tubular devices and one or more vacuum coating chambers, positioning the one or more tubular devices in the one or more vacuum coating chambers, wherein at least a portion of the one or more tubular devices extends outside of the one or more vacuum coating chambers, forming one or more vacuum seals between the outside surface of the one or more tubular devices and one or more walls of the one or more vacuum coating chambers, pulling a vacuum inside the one or more vacuum coating chambers around one or more portions of the outer surface of the one or more tubular devices for coating, and forming a coating on one or more portions of the outer surface of the one or more tubular devices via a vacuum deposition method.

2. The method of clause 1, wherein the vacuum deposition method is physical vapor deposition, selected from the group consisting of magnetron sputtering, ion beam assisted deposition, cathodic arc deposition, pulsed laser deposition, and combinations thereof.

3. The method of clause 1, wherein the vacuum deposition method is chemical vapor deposition, selected from the group consisting of ion beam assisted chemical vapor deposition, plasma assisted chemical vapor deposition, plasma immersed ion processing, microwave discharge, and combinations thereof.

4. The method of clauses 1-3, wherein the one or more vacuum seals between the outside surface of the one or more tubular devices and the one or more walls of the one or more vacuum coating chambers are formed using a sacrificial ductile material, an adhesive seal material, an air door, a vacuum seal adapter or a combination thereof.

5. The method of clause 4, wherein the sacrificial ductile material is selected from the group consisting of aluminum, steel, tin, copper, and alloys of aluminum, iron, tin, and copper, and a plastic/resin material.

6. The method of clause 4, wherein the adhesive seal material is a urethane or an epoxy.

7. The method of clauses 1-6, wherein the one or more tubular devices include drill stem equipment, casing, tubing, work strings, coiled tubing, pipes, risers, and completion strings and equipment.

8. The method of clauses 1-7, wherein one tubular device is positioned within one vacuum coating chamber.

9. The method of clause 8, wherein one end of the tubular device is positioned within the one vacuum coating chamber.

10. The method of clauses 8-9, further including sealing the one end of the tubular device positioned within the one vacuum coating chamber by inserting a vacuum-tight end cap within the inside diameter of the tubular device.

11. The method of clauses 1-7, wherein one tubular device is positioned within two vacuum coating chambers.

12. The method of clause 11, wherein one end of the tubular device is positioned within one of the two vacuum coating chambers.

13. The method of clause 11, wherein each end of the tubular device is positioned within each of the two vacuum coating chambers.

14. The method of clauses 11-13, further including sealing at least one end of the tubular device positioned within the two vacuum coating chambers by inserting a vacuum-tight end cap within the inside diameter of the tubular device.

15. The method of clauses 1-14, wherein the coating is selected from the group consisting of an amorphous alloy, an electroless nickel-phosphorous composite, graphite, MoS₂, WS₂, a fullerene based composite, a boride based cermet, a quasicrystalline material, diamond, a diamond based material, diamond-like-carbon, boron nitride, chromium nitride, silicon nitride, silicon carbide, carbon nanotubes, graphene sheets, metallic particles of high aspect ratio, ring-shaped materials, oblong particles and combinations thereof.

16. The method of clauses 1-15 wherein the one or more tubular devices further include one or more regions of hardbanding on at least at a portion of the outside surface.

17. The method of clause 16, wherein at least one region of hardbanding is used to form the one or more vacuum seals between the outside surface of the one or more tubular devices and the one or more outside walls of the one or more vacuum coating chambers.

18. The method of clauses 16-17, wherein the at least one region of hardbanding used to form the one or more vacuum seals includes a differential hardness as a function of tubular device axial length, a differential thickness as a function of tubular device axial length or a combination thereof.

19. The method of clause 16-18, wherein the at least one region of hardbanding used to form the one or more vacuum seals further includes a sacrificial ductile material, an adhesive seal material or a combination thereof, located on top of, adjacent to, or in proximity to said at least one region of hardbanding.

20. The method of clauses 16-19, wherein the hardbanding is selected from the group consisting of cermet based materials, metal matrix composites, nanocrystalline metallic alloys, amorphous alloys, hard metallic alloys, carbides, nitrides, borides, and oxides of elemental tungsten, titanium, niobium, molybdenum, iron, chromium, and silicon dispersed within a metallic alloy matrix.

21. The method of clauses 16-20, further including coating at least a portion of the one or more regions of hardbanding.

22. The method of clauses 1-7 and 11-21, wherein the one or more vacuum coating chambers are placed within one another.

23. The method of clauses 1-22, further including rotating or moving the one or more tubular devices in the vacuum coating chamber during the coating step.

24. The method of clauses 1-23, further including providing within the vacuum coating chamber a rotatable or moveable coating source geometry around the outside surface of the one or more tubular devices and rotating or moving the coating source geometry during the coating step.

25. The method of clauses 1-24, further including surface treating the outside surface of the one or more tubular devices prior to the coating step.

26. The method of clause 25, wherein the surface treating step occurs inside the one or more vacuum coating chambers, a surface treatment chamber, or in an ambient environment.

27. The method of clauses 25-26, wherein said surface treating step is selected from the group consisting of ultrasonic cleaning, polishing, etching, grinding, solvent cleaning, sandblasting, hardbanding, and combinations thereof.

28. The method of clauses 1-7 and 11-27, wherein the one or more vacuum coating chambers are connected to a central vacuum pump source, a central power source, or a combination thereof.

Applicants have attempted to disclose all embodiments and applications of the disclosed subject matter that could be reasonably foreseen. However, there may be unforeseeable, insubstantial modifications that remain as equivalents. While the present invention has been described in conjunction with specific, exemplary embodiments thereof, it is evident that many alterations, modifications, and variations will be apparent to those skilled in the art in light of the foregoing description without departing from the spirit or scope of the present disclosure. Accordingly, the present disclosure is intended to embrace all such alterations, modifications, and variations of the above detailed description.

All patents, test procedures, and other documents cited herein, including priority documents, are fully incorporated by reference to the extent such disclosure is not inconsistent with this invention and for all jurisdictions in which such incorporation is permitted.

When numerical lower limits and numerical upper limits are listed herein, ranges from any lower limit to any upper limit are contemplated.

1. A method of coating a portion of the outer surface of a tubular device used in oil and gas drilling, completions and production operations comprises: providing one or more tubular devices and one or more vacuum coating chambers, positioning the one or more tubular devices in the one or more vacuum coating chambers, wherein at least a portion of the one or more tubular devices extends outside of the one or more vacuum coating chambers, forming one or more vacuum seats between the outside surface of the one or more tubular devices and one or more walls of the one or more vacuum coating chambers, pulling a vacuum inside the one or more vacuum coating chambers around one or more portions of the outer surface of the one or more tubular devices for coating, and forming a coating on one or more portions of the outer surface of the one or more tubular devices via a vacuum deposition method.

2. The method of clause 1, wherein the vacuum deposition method is physical vapor deposition, selected from the group consisting of magnetron sputtering, ion beam assisted deposition, cathodic arc deposition, pulsed laser deposition, and combinations thereof.

3. The method of clause 1, wherein the vacuum deposition method is chemical vapor deposition, selected from the group consisting of ion beam assisted chemical vapor deposition, plasma assisted chemical vapor deposition, plasma immersed ion processing, microwave discharge, and combinations thereof.

4. The method of clauses 1-3, wherein the one or more vacuum seals between the outside surface of the one or more tubular devices and the one or more walls of the one or more vacuum coating chambers are formed using a sacrificial ductile material, an adhesive seal material, an air door, a vacuum seal adapter or a combination thereof.

5. The method of clause 4, wherein the sacrificial ductile material is selected from the group consisting of aluminum, steel, tin, copper, and alloys of aluminum, iron, tin, and copper, and a plastic/resin material.

6. The method of clause 4, wherein the adhesive seal material is a urethane or an epoxy.

7. The method of clauses 1-6, wherein the one or more tubular devices include drill stem equipment, casing, tubing, work strings, coiled tubing, pipes, risers, and completion strings and equipment.

8. The method of clauses 1-7, wherein one tubular device is positioned within one vacuum coating chamber.

9. The method of clause 8, wherein one end of the tubular device is positioned within the one vacuum coating chamber.

10. The method of clauses 8-9, further including sealing the one end of the tubular device positioned within the one vacuum coating chamber by inserting a vacuum-tight end cap within the inside diameter of the tubular device.

11. The method of clauses 1-7, wherein one tubular device is positioned within vacuum coating chambers.

12. The method of clause 11, wherein one end of the tubular device is positioned within one of the two vacuum coating chambers.

13. The method of clause 11 wherein each end of the fibular device is positioned within each of the two vacuum coating chambers.

14. The method of clauses 11-13 further including sealing at least one end of the tubular device positioned within the two vacuum coating chambers by inserting a vacuum-tight end cap within the inside diameter of the tubular device.

15. The method of clauses 1-14, wherein the coating is selected from the group consisting of an amorphous alloy, an electroless nickel-phosphorous composite, graphite, MoS₂, WS₂, a fullerene based composite, a boride based cermet, a quasicrystalline material, diamond, a diamond based material, diamond-like-carbon, boron nitride, chromium nitride, silicon nitride, silicon carbide, carbon nanotubes, graphene sheets, metallic particles of high aspect ratio, ring-shaped materials, oblong particles and combinations thereof.

16. The method of clauses 1-15, wherein the one or more tubular devices further include one or more regions of hardbanding on at least at a portion of the outside surface.

17. The method of clause 16, wherein at least one region of hardbanding is used to form the one or more vacuum seals between the outside surface of the one or more tabular devices and the one or more outside walls of the one or more vacuum coating chambers.

18. The method of clauses 16-17, wherein the at least one region of hardbanding used to form the one or more vacuum seals includes a differential hardness as a function of tubular device axial length, a differential thickness as a function of tubular device axial length or a combination thereof.

19. The method of clause 16-18, wherein the at least one region of hardbanding used to form the one or more vacuum seals further includes a sacrificial ductile material, an adhesive seal material or a combination thereof, located on top of adjacent to, or in proximity to said at least one region of hardbanding.

20. The method of clauses 16-19, wherein the hardbanding is selected from the group consisting of cermet based materials, metal matrix composites, nanocrystalline metallic alloys, amorphous alloys, hard metallic alloys, carbides, nitrides, borides, and oxides of elemental tungsten, titanium, niobium, molybdenum, iron, chromium, and silicon dispersed within a metallic alloy matrix.

21. The method of clauses 16-20 further including coating at least a portion of the one or more regions of hardbanding.

22. The method of clauses 1-7 and 11-21, wherein the one or more vacuum coating chambers are placed within one another.

23. The method of clauses 1-22, further including rotating or moving the one or more tubular devices in the vacuum coating chamber during the coating step.

24. The method of clauses 1-23, further including providing within the vacuum coating chamber a rotatable or moveable coating source geometry around the outside surface of the one or more tubular devices and rotating or moving the coating source geometry during the coating step.

25. The method of clauses 1-24, further including surface treating the outside surface of the one or more tubular devices prior to the coating step.

26. The method of clause 25, wherein the surface treating step occurs inside the one or more vacuum coating chambers, a surface treatment chamber, or in an ambient environment.

27. The method of clauses 25-26, wherein said surface treating step is selected from the group consisting of ultrasonic cleaning, polishing, etching, grinding, solvent cleaning, sandblasting, hardbanding, and combinations thereof.

28. The method of clauses 1-7 and 1-27, wherein the one or more vacuum coating chambers are connected to a central vacuum pump source, a central power source, or a combination thereof.
